(19) United States
(12) Patent Application Publication
(10) Pub. No.: US 2026/0326468 A1
(43) Pub. Date: Oct. 22, 2026

(54) IMAGE FORMING APPARATUS

(71) Applicant: KYOCERA Document Solutions Inc., Osaka (JP)

(72) Inventors: Shizuya Uemura, Osaka (JP); Takashi Inoue, Osaka (JP); Eiji Nakayama, Osaka (JP)

(21) Appl. No.: 19/642,579

(22) Filed: Apr. 8, 2026

(30) Foreign Application Priority Data
Apr. 18, 2025 (JP) 2025-068924

(51) Int. Cl. B41J 29/393; B41J 2/175; B41J 3/44; H01Q 1/38; H01Q 1/52; H05K 1/02; H05K 1/18

(52) U.S. Cl. CPC B41J 29/393; B41J 2/17546; B41J 3/44; H01Q 1/38; H01Q 1/521; H05K 1/0224; H05K 1/18; B41J 2029/3937; H05K 2201/10098; H05K 2201/10545

(57) ABSTRACT

An image forming apparatus includes plural antennas and ground area members. The plural antennas are configured to communicate with wireless tags on plural ink tank units detachable in the image forming apparatus, respectively. The ground area members are electrically connected to a ground and each of the ground area members is installed between two antennas close to each other among the plural antennas.

### CROSS-REFERENCE TO RELATED APPLICATIONS

This application relates to and claims priority rights from Japanese Patent Application No. 2025-068924, filed on Apr. 18, 2025, the entire disclosures of which are hereby incorporated by reference herein.

### BACKGROUND

### 1. Field of the Present Disclosure

The present disclosure relates to an image forming apparatus.

### 2. Description of the Related Art

An image forming apparatus includes an antenna capable of communication with an RFID tag in a detachable ink tank unit, reads identification information from the RFID tag using the antenna, and determines whether the ink tank unit is a genuine product or not on the basis of the identification information.

FIG. 3 shows a side-view diagram that indicates an example of a configuration of an ordinary image forming apparatus. As shown in FIG. 3 for example, wireless tags 11 are fixed on plural ink tank units 1, respectively, and on a circuit board 101, antennas 111 are installed such that the antennas 111 face the wireless tags 11 without contact. As shown in FIG. 3 for example, if the antennas 111 are arranged so as to be close to each other, when one of the antennas 111 communicates with the facing wireless tag 11, this antenna 111 may interfere with another adjacent antenna 111 or another wireless tag 11 and thereby communication with the wireless tag 11 may not be properly performed.

### SUMMARY

An image forming apparatus according to an aspect of the present disclosure includes plural antennas and ground area members. The plural antennas are configured to communicate with wireless tags on plural ink tank units detachable in the image forming apparatus, respectively. The ground area members are electrically connected to a ground, each of the ground area members installed between two antennas close to each other among the plural antennas.

These and other objects, features and advantages of the present disclosure will become more apparent upon reading of the following detailed description along with the accompanied drawings.

### BRIEF DESCRIPTION OF THE DRAWINGS

FIG. 1 shows a perspective-view diagram that indicates a configuration of an image forming apparatus according to an embodiment of the present disclosure;

FIG. 2 shows a side-view diagram that indicates a configuration of an image forming apparatus according to an embodiment of the present disclosure; and

FIG. 3 shows a side-view diagram that indicates an example of a configuration of an ordinary image forming apparatus.

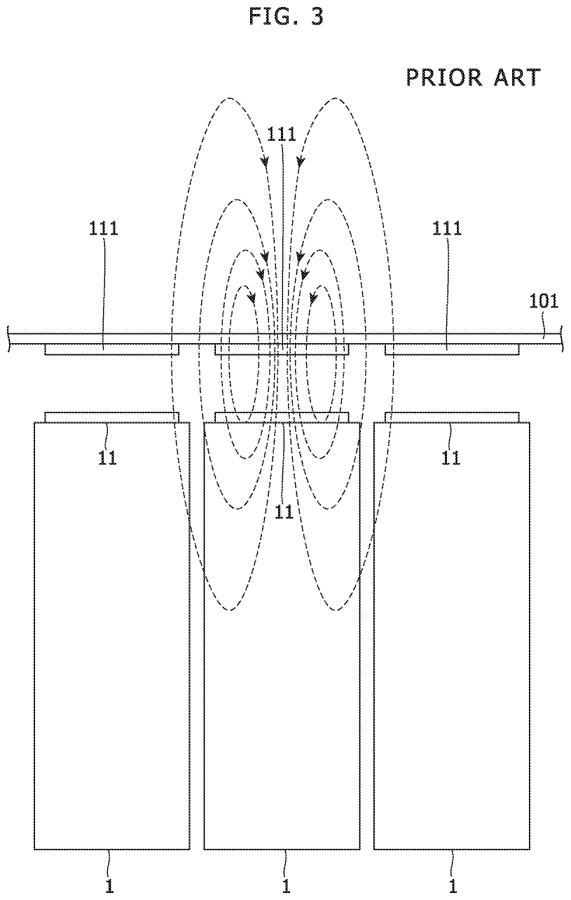

### DETAILED DESCRIPTION

Hereinafter, an embodiment according to an aspect of the present disclosure will be explained with reference to drawings.

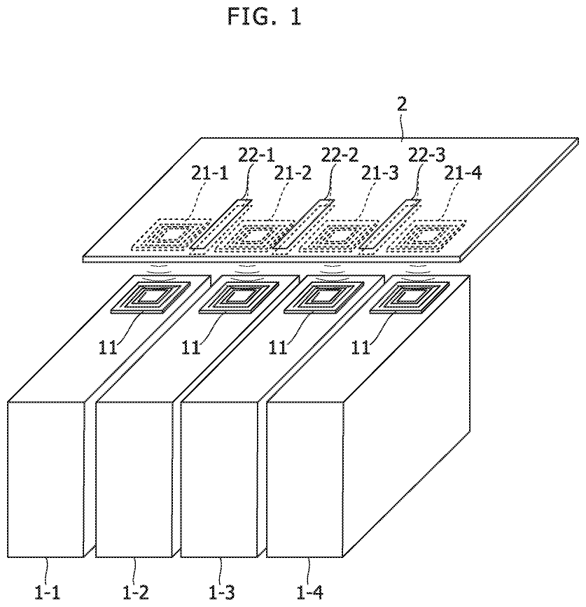

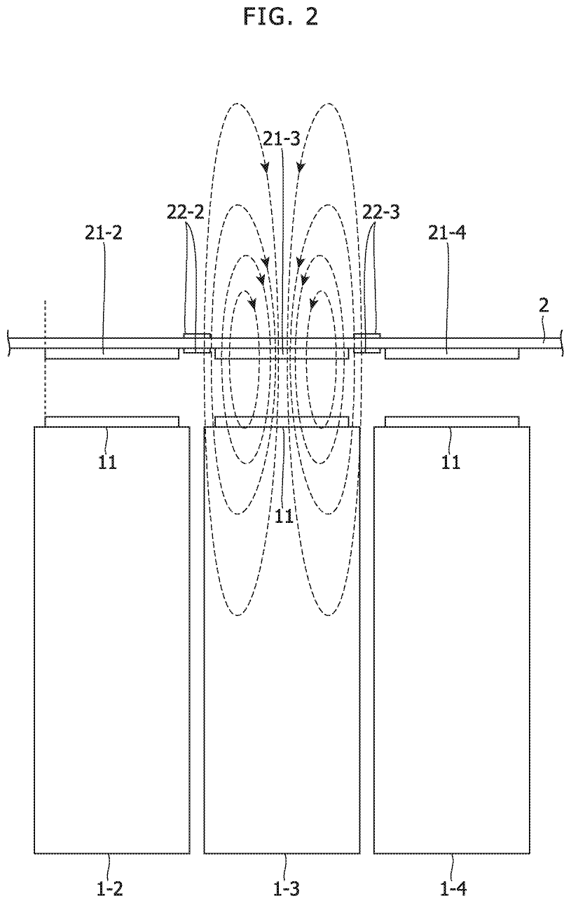

FIG. 1 shows a perspective-view diagram that indicates a configuration of an image forming apparatus according to an embodiment of the present disclosure. FIG. 2 shows a side-view diagram that indicates a configuration of an image forming apparatus according to an embodiment of the present disclosure. The image forming apparatus shown in FIGS. 1 and 2 is a color inkjet printer, a color inkjet multi function peripheral or the like, for example, and in this image forming apparatus, plural ink tank units 1-1 to 1-4 of ink of plural colors (e.g. Cyan, Magenta, Yellow and Black) are detachable. Each of the ink tank units 1-1 to 1-4 has a substantially cuboid shape, and the ink tank units 1-1 to 1-4 are arranged so as to be close to each other in line as shown in FIG. 1, for example. Each of the ink tank units 1-1 to 1-4 contains ink in an internal ink storage unit of it. Here, in the ink tank units 1-1 to 1-4, ink of Cyan, Magenta, Yellow and Black is contained, respectively.

Each of the ink tank units 1-1 to 1-4 includes a wireless tag 11 (here, RFID). In the wireless tag 11, stored are identification information, property information (Point of Production information, toner counter information, and/or the like) and the like of the ink tank unit 1-i. Here, the wireless tags 11 are arranged at the same positions in upper surfaces of the ink tank units 1-1 to 1-4.

Further, the image forming apparatus includes plural antennas 21-1 to 21-4, and ground area members 22-1 to 22-3.

The plural antennas 21-1 to 21-4 communicate with the wireless tags 11 on the plural ink tank units 1-1 to 1-4, respectively.

The ground area members 22-1 to 22-3 are plate-shaped members that are electrically connected to a ground of this image forming apparatus (specifically, a ground of a controller mentioned below), and each of the ground area members 22-1 to 22-3 is installed between two antennas 21-i and 21-j close to each other among the plural antennas 21-1 to 21-4. Because of the ground area members 22-1 to 22-3, when an antenna 21-i communicates with a facing wireless tag 11, the antenna 21-i does not easily interfere another adjacent antenna 21-j or another wireless tag 11 (a magnetic flux of the antenna 21-i does not make interlinkage with another antenna 21-j or another wireless tag 11 as shown in FIG. 2, for example), and thereby communication with the wireless tag 11 is properly performed.

In this embodiment, the image forming apparatus includes a printed wiring board 2, and the plural antennas 21-1 to 21-4 are arranged in line, installed on the printed wiring board 2, and fixed at positions that face the wireless tags 11 of the ink tank units 1-1 to 1-4, respectively. Further, the ground area members 22-1 to 22-3 are a printed wiring on the printed wiring board 2.

Further, in this embodiment, the printed wiring board 2 is a double-sided circuit board, and each of the ground area members 22-k includes a first member installed on one surface of the printed wiring board 2 where the antennas 21-1 to 21-4 are installed, and a second member installed on the other surface of the printed wiring board 2. As shown in FIG. 2 for example, the second member is installed at a position that faces the first member through the printed wiring board 2.

The image forming apparatus further includes a printing device, a controller, and the like. The printing device performs printing using the ink in the ink tank units 1-1 to 1-4. The controller includes a microcomputer, an ASIC (Application Specific Integrated Circuit) and/or the like, causes the printing device to perform printing, and reads and writes data (the aforementioned identification information and/or the property information) from/to the wireless tags 11 of the ink tank units 1-1 to 1-4 using the antennas 21-1 to 21-4.

The following part explains a behavior of the aforementioned image forming apparatus.

The controller communicates with the wireless tags 11 of the ink tank units 1-1 to 1-4 using the antennas 21-1 to 21-4 and thereby reads and writes the aforementioned data. At that time, a radio wave is emitted from the antenna 21-i and sensed by the antenna of the wireless tag 11. Here, the radio wave is attenuated by the ground area members 22-1 to 22-3, and does not easily reach another wireless tag 11 or another antenna 21-j.

For example, the controller applies a carrier wave of a predetermined intensity to the antenna 21-i and thereby the carrier wave is emitted from the antenna 21-i to the wireless tag 11. Further, the wireless tag 11 changes an impedance of the built-in antenna correspondingly to data to be transmitted and changes a reflection intensity, and thereby emits a modulated wave. Further, the antenna 21-i senses the modulated wave from the wireless tag 11, and the controller acquires data from the wireless tag 11 on the basis of the modulated wave.

As mentioned, in the aforementioned embodiment, the plural antennas 21-1 to 21-4 communicate with the wireless tags 11 on the plural ink tank units 1-1 to 1-4 detachable in this image forming apparatus, respectively. The ground area members 22-1 to 22-3 are electrically connected to a ground, and each of the ground area members 22-1 to 22-3 is installed between two antennas close to each other among the plural antennas 21-1 to 21-4.

Consequently, even if the ink tank units 1-1 to 1-4 (the wireless tags 11) are close to each other, namely even if the antennas 21-1 to 21-4 are close to each other, the ground area members 22-1 to 22-3 restrains interference between the antennas 21-i and 21-j and communication with the wireless tags 11 on the ink tank units 1-1 to 1-4 are properly performed (even if an anti-collision function is not used).

It should be understood that various changes and modifications to the embodiments described herein will be apparent to those skilled in the art. Such changes and modifications may be made without departing from the spirit and scope of the present subject matter and without diminishing its intended advantages. It is therefore intended that such changes and modifications be covered by the appended claims.

For example, in the aforementioned embodiment, the controller may not have an anti-collision function because the ground area members 22-1 to 22-3 restrains interference between the antennas.

What is claimed is:

1. An image forming apparatus, comprising:
plural antennas configured to communicate with wireless tags on plural ink tank units detachable in the image forming apparatus, respectively; and
ground area members electrically connected to a ground, each of the ground area members installed between two antennas close to each other among the plural antennas.

2. The image forming apparatus according to claim 1, further comprising a printed wiring board;
wherein the plural antennas are arranged in array and installed on the printed wiring board; and
the ground area members are a print wiring on the printed wiring board.

3. The image forming apparatus according to claim 2, wherein the printed wiring board is a double-sided circuit board; and
the ground area member comprises a first member installed on one surface of the printed wiring board where the antennas are installed, and a second member installed on the other surface of the printed wiring board.
